(19) United States
(12) Patent Application Publication
(10) Pub. No.: US 2003/0197155 A1
(43) Pub. Date: Oct. 23, 2003

(54) Mercury-containing copper oxide superconductor film, manufacturing apparatus thereof and manufacturing process thereof

(75) Inventor: Wataru Hattori, Tokyo (JP)

Correspondence Address: PATENT GROUP, CHOATE, HALL & STEWART, EXCHANGE PLACE, 53 STATE STREET, BOSTON, MA, 02109, US

(73) Assignee: NEC Corporation

(21) Appl. No.: 10/191,894

(22) Filed: Jul. 9, 2002

(30) Foreign Application Priority Data
Jul. 16, 2001 (JP) 2001-215959

(51) Int. Cl. C23C 16/00; H01C 1/00

(52) U.S. Cl. 252/500; 118/715; 118/726; 427/62; 427/255.21

(57) ABSTRACT

The objective of this invention is to provide a mercury-containing copper oxide superconductor film with a large area and a reduced amount of hetero-phase precipitate as an impurity, as well as an apparatus and a process for safely producing the film in a large scale; for this purpose, an apparatus for forming a film of this invention comprises a pressure vessel 1 (pressurized atmosphere furnace) equipped with a port 11 for introducing an external gas atmosphere to the furnace wall 3 and a mercury feeder 10 for controlling a pressure of the gas atmosphere independently of the pressure vessel 1 by generating a mercury-containing gas, the mercury feeder 10 introduces a mercury-containing gas into the pressure vessel 1 via the port 11, and, there is a metal seal gate valve 16 between the pressure vessel 1 and the mercury feeder 10.

### BACKGROUND OF THE INVENTION

1. Field of the Invention

This invention relates to a film of mercury-containing copper oxide superconductor (Hg₁₋ₓAₓ)BCₙ₋₁CuₙO_{2n+2+δ}, wherein A is an element such as Re, Tl, Pb and Cu or a mixture thereof; B is an element such as Ba, Sr and La or a mixture thereof; C is an element such as Ca, Sr and Y or a mixture thereof; X is a real number from zero inclusive to less than one; and n is a natural number of 1, 2 or 3; an apparatus for manufacturing the film; and a process for manufacturing the film. In particular, this invention relates to a film of mercury-containing copper oxide superconductor, which generates a less amount of hetero-phase precipitate as an impurity; an apparatus for manufacturing the film; and a process for manufacturing the film.

2. Description of the Prior Art

A mercury-containing copper oxide superconductor has a higher superconductive transition temperature and can be readily cooled. It is, therefore, expected to find applications in electronic devices such as a bandpass filter used for a base station receiver in a mobile telecommunication system. For producing such a superconductor, it is necessary to form a film of a mercury-containing copper oxide superconductor epitaxially grown along a c-axis, on one or both sides of an insulating substrate exhibiting good crystallinity such as an MgO single crystal substrate.

In general, a superconductor film is formed on a substrate surface by heating the substrate on which a precursor film has been preformed in a sealed quartz-tube vessel equipped with a container (crucible) in which the substrate is disposed and a container (crucible) in which a source for a substance to be a raw material for forming a film is disposed, while individually controlling temperatures of the crucibles, as according to a process for preparing compounds described in JP-A 8-259204. For example, when the material source is a mercury-containing composition, a film can be formed by controlling a temperature of the crucible in which the composition is disposed to control a partial pressure of mercury in the sealed container while controlling a temperature of the crucible in which the substrate is disposed.

However, the manufacturing process described in JP-A 8-259204 adjusts a temperature of each crucible in the same sealed vessel. It is, therefore, very difficult to independently control the temperatures, due to effects of radiation heat, solid heat conduction via the wall of the sealed vessel and thermal conduction via a gas within the sealed vessel. When producing a mercury-containing copper oxide superconductor, a quartz vessel may be exploded because a mercury pressure may be rapidly increased even at a relatively lower temperature. For this reason, a withstanding pressure of a sealed vessel should be high enough, and, for example, a small and extremely thick quartz tube with an inner diameter of 7 mm to at most about 15 mm must be used as a sealed vessel.

When using such a process, a temperature of a mercury source cannot be adequately reduced to completely stop supplying mercury to a precursor film even when the substrate temperature of the precursor film is as low as about 500° C. When mercury is supplied to the precursor film at a temperature around 500° C., HgCaO₂ which is stable around the temperature and is a hetero-phase impurity for a mercury-containing copper oxide superconductor is precipitated. Thus, when using such a process, a hetero-phase precipitate cannot be eliminated in a film of a mercury-containing copper oxide superconductor.

For solving the problems, Odier et al. (P. Odier, A. Sin, P. Toulemonde, A. Bailly and S. Le. Floch, Superconductor Science & Technology, Vol. 13, pp. 1120-1128, 2000, Institute Of Physics) has disclosed that a reaction period can be reduced by rapid temperature rising of 10° C. or more per minute in a particular temperature range (in particular, around 500° C.) to minimize the amount of precipitated HgCaO₂.

Even when the process described in the reference is employed, a reaction time between the precursor film and mercury in a temperature range of around 500° C. cannot be completely eliminated. Thus, precipitation of HgCaO₂ cannot be inhibited; specifically, it is difficult to reduce the amount of the precipitate to a volume fraction of 5% or less. This reaction is also conducted in a small volume sealed vessel so that it considerably depends on particular factors such as the amount of mercury and an area of the precursor film. It, therefore, requires precise measurement of mercury charged in the vessel in each run, which may be troublesome for an operator.

For producing a filter for a mobile telecommunication system, particularly that which can deal with a 2 GHz band, a large area film with a diameter of about 75 mm to 100 mm is generally required if the filter is circular. A film used as a filter for a mobile telecommunication system is required to have improved superconductor properties such as a higher superconductive transition temperature, a higher critical current density and a lower surface resistance. There is, therefore, needed a film containing a reduced amount of impurities, specifically a film in which ideally no impurities are precipitated, or if any, the amount of the precipitate is contained at a volume fraction of at least 5% or less to the total volume of the film.

The manufacturing apparatuses and the manufacturing processes described above cannot provide a mercury-containing copper oxide superconductor suitable for a filter for a mobile telecommunication system. The manufacturing apparatuses and the manufacturing processes require precise measurement of the amount of mercury charged and cannot, therefore, meet the requirements for mass productiveness needed for a filter for a mobile telecommunication system. Furthermore, in the manufacturing apparatus, a film is formed in a small volume sealed vessel so that a large area film cannot be formed.

Thus, an objective of this invention is to provide a mercury-containing copper oxide superconductor film with a large area and a reduced amount of hetero-phase precipitate as an impurity; as well as an apparatus and a process for safely producing the film in a large scale.

### SUMMARY OF THE INVENTION

In the first aspect, this invention provides a mercury-containing copper oxide superconductor film which is substantially made of a single phase and is free of a hetero phase.

In the second aspect, this invention provides a mercury-containing copper oxide superconductor film containing HgCaO₂ as a hetero phase at a volume fraction of 5% or less. The film according to this invention is substantially made of a single phase and is free of a hetero phase. The film of this invention, therefore, has improved superconductor properties such as a higher superconductive transition temperature, a higher critical current density and a lower surface resistance, so that it can be employed for an electronic device such as a filter for a mobile telecommunication system.

In the third aspect, this invention provides an apparatus for producing a mercury-containing copper oxide superconductor film comprising a system for controlling a temperature of a mercury-containing gas atmosphere and a system for controlling a pressure of a gas atmosphere independently of the temperature of the mercury-containing gas atmosphere.

In the fourth aspect, this invention provides an apparatus for producing a mercury-containing copper oxide superconductor film comprising a pressurized atmosphere furnace equipped with a port for introducing an external gas atmosphere to the furnace wall as the system for controlling a temperature of a mercury-containing gas atmosphere and a mercury gas generator for controlling a pressure of the gas atmosphere independently of the pressurized atmosphere furnace by generating a mercury-containing gas as the system for controlling a pressure of a gas atmosphere independently of the temperature of the mercury-containing gas atmosphere, wherein the mercury gas generator introduces a mercury-containing gas into the pressurized atmosphere furnace via the port. In this configuration, a film is produced in a pressurized atmosphere furnace which is a large volume sealed vessel, rather than a small volume sealed vessel such as a quartz tube. A reaction is, therefore, not dependent on, for example, an area of a precursor film. Furthermore, mercury is fed via a separate system so that a partial pressure of mercury can be precisely controlled independently of the temperature conditions in the pressurized atmosphere furnace. This apparatus can deal with mass production of a large area substrate for preparing an electronic device such as a filter for a mobile telecommunication system.

In the fifth aspect, this invention provides an apparatus for producing a mercury-containing copper oxide superconductor film comprising a gate valve between the pressurized atmosphere furnace and the mercury gas generator. In this configuration, both heat and gas flows from the pressurized atmosphere furnace to the mercury gas generator and from the mercury gas generator to the pressurized atmosphere furnace can be completely inhibited. A pressure and a temperature of the gas atmosphere within the mercury gas generator can be controlled considerably independently of control in the pressurized atmosphere furnace. Thus, a gas atmosphere in the pressurized atmosphere furnace can be free of mercury so that a mercury-containing copper oxide superconductor film can be formed under the conditions whereby precipitation of HgCaO₂ as a hetero phase can be completely inhibited.

In the sixth aspect, this invention provides an apparatus for producing a mercury-containing copper oxide superconductor film wherein the gate valve is a metal seal type gate valve and is heatable. In this apparatus, adhesion of mercury to the gate valve can be prevented, resulting in minimizing failure of the gate valve. Furthermore, temperatures within the mercury generator and the gate valve can be adjusted so that mercury can be aggregated and adsorbed in the mercury generator, resulting in improvement in safety.

In the seventh aspect, this invention provides an apparatus for producing a mercury-containing copper oxide superconductor film wherein the mercury gas generator comprises a crucible for generating a mercury-containing gas atmosphere by heating a mercury-containing composition to control a pressure of the gas atmosphere utilizing vapor pressure equilibrium. Using this apparatus, a vapor pressure of a mercury compound such as mercury oxide and a mercury halide can be utilized to readily control a partial pressure of mercury. Since this apparatus utilizes vapor pressure equilibrium, a partial pressure of mercury is dependent on a crucible temperature alone, which can eliminate the necessity for precise measurement of the amount of mercury as is in a common process for producing a mercury-containing copper oxide superconductor film.

In the eighth aspect, this invention provides an apparatus for producing a mercury-containing copper oxide superconductor film wherein a component used in a seal in the apparatus is made of Fe, Ni, Co, Mn or an alloy mainly comprising Fe, Ni, Co or Mn, or is coated with Fe, Ni, Co, Mn or an alloy mainly comprising Fe, Ni, Co or Mn. This configuration can prevent the seal from being amalgamated by mercury and thus from being deteriorated. Specifically, it can prevent melting-point reduction and deterioration of mechanical properties in the seal. It can thus prevent leakage of mercury gas due to deterioration of the seal to ensure safety.

In the ninth aspect, this invention provides an apparatus for producing a mercury-containing copper oxide superconductor film further comprising a housing enclosing an apparatus unit inside of which is filled with a mercury-containing gas atmosphere and an exhauster for forcibly exhausting the inside of the housing. Using the apparatus, even if a mercury gas leaks from, e.g., the pressurized atmosphere furnace, the gas can be forcibly exhausted to ensure security of people workers around the manufacturing apparatus.

In the tenth aspect, this invention provides a process for producing a mercury-containing copper oxide superconductor film comprising the steps of forming a precursor film comprising a mercury-containing copper oxide superconductor composite on a substrate and placing the product in a furnace; controlling a furnace temperature while controlling a pressure of the mercury-containing gas atmosphere independently of temperature control; and introducing gaseous mercury to the precursor film disposed within the furnace and diffusing mercury in the precursor film or reacting mercury with the film.

In eleventh aspect, this invention provides a process for producing a mercury-containing copper oxide superconductor film wherein mercury is fed into the furnace under the conditions such that mercury can be diffused in or reacted with the precursor film to form a sintered mercury-containing copper oxide superconductor. Generally, measurements of a furnace temperature and pressure have a margin of error, depending on a way of placing a thermometer or pressure gauge. Therefore, in forming a film, a temperature and a pressure must be optimized for each furnace. As is in this aspect, a film can be formed under the conditions providing a sintered body so that optimal film forming conditions can be found for each furnace even under the conditions having a margin of error inherent to the furnace.

In the twelfth aspect, this invention provides a process for producing a mercury-containing copper oxide superconductor film wherein using MgO as a material for a substrate, mercury is introduced into the furnace while maintaining the furnace at an internal temperature of 800° C. or less. This process can form a mercury-containing copper oxide superconductor film exhibiting good properties.

In the thirteenth aspect, this invention provides a process for producing a mercury-containing copper oxide superconductor film wherein a plurality of prototypes of a mercury-containing copper oxide superconductor are made for adjusting a final cation ratio to a stoichiometric ratio or for determining a cation ratio in the precursor film such that the ratio is higher than the stoichiometric ratio and a Cu composition ratio is 7% or less. According to this process, a plurality of prototypes for the film can be made to obtain data for a cation ratio, which can be fed back to adjust the ratio to a stoichiometric ratio for provide a film exhibiting good superconductor properties in which precipitation of an impurity layer is reduced. On the other hand, the ratio can be higher than the stoichiometric ratio while adjusting a Cu composition ratio to 7% or less, to produce a film exhibiting improved superconductor properties such as a higher superconductive transition temperature in comparison with a film prepared with the stoichiometric ratio, although the amount of a Cu-containing precipitate is increased.

In the fourteenth aspect, this invention provides a process for producing a mercury-containing copper oxide superconductor film wherein the internal temperature of the furnace reaches a temperature at which the mercury-containing copper oxide superconductor is thermodynamically stably formed, before introducing mercury. According to this process, mercury gas is not introduced into the furnace until the internal temperature reaches a temperature at which the mercury-containing copper oxide superconductor can be thermodynamically stably formed (about 800° C.). Thus, mercury gas is not introduced at an intermediate temperature of around 500° C., and therefore, generation of HgCaO₂ can be theoretically avoided. As such, the amount of precipitated HgCaO₂ as an impurity can be reduced to a volume fraction of 5% or less to form a mercury-containing copper oxide superconductor film substantially free of a hetero phase.

### BRIEF DESCRIPTION OF THE DRAWINGS

FIG. 1 schematically shows a configuration example of an apparatus for producing a mercury-containing copper oxide superconductor film according to this invention.

FIG. 2 shows a production process for a mercury-containing copper oxide superconductor film according to this invention.

FIG. 3 illustrates exemplary results of testing superconductor properties.

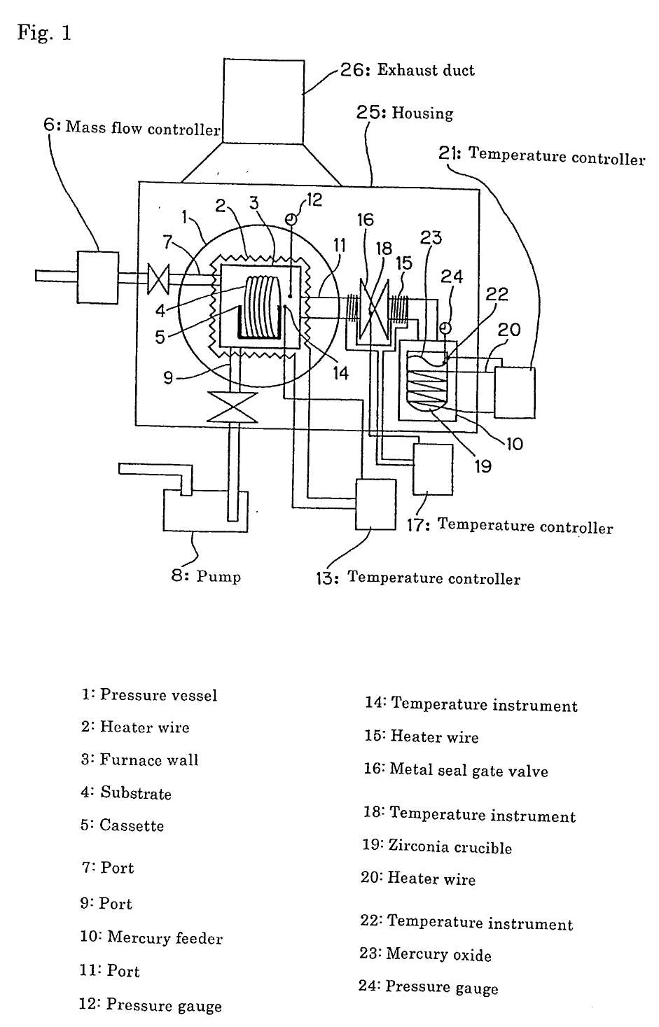

In FIG. 1, 1 is a pressure vessel; 2, 15 and 20 are heater wires; 3 is a furnace wall; 4 is a substrate; 5 is a cassette; 7, 9 and 11 are ports; 10 is a mercury feeder; 12 is a pressure gauge; 14, 18 and 22 are temperature instruments; 16 is a metal seal gate valve; 19 is a zirconia crucible; 23 is mercury oxide; and 24 is a pressure gauge.

### DETAILED DESCRIPTION OF PREFERRED EMBODIMENTS

Embodiments of this invention will be described with reference to the drawings. FIG. 1 schematically shows a configuration example of an apparatus for producing a mercury-containing copper oxide superconductor film according to this invention.

In the manufacturing apparatus shown in FIG. 1, a furnace wall 3 is disposed within the pressure vessel 1 as a pressured atmosphere furnace and a heater wire 2 is wound around the furnace wall 3. In the furnace wall 3 (the furnace inside), a cassette 5 for accommodating a precursor film is placed. In the apparatus shown in FIG. 1, on an MgO (100) substrate 4 with a diameter of 3 inch is deposited a precursor film with a composition of Re_{0.18}Ba_{2.02}CaCu_{2.03}Oₓ to 500 nm, on which is further deposited ReO as a barrier film to 10 nm. Six pieces of the substrate 4 are disposed in the cassette 5. In contrast to a small volume sealed vessel such as a quartz tube, this apparatus can deal with mass production of a large area superconductor film substrate for producing a filter for a mobile telecommunication system. The ReO barrier film can prevent the components in the precursor (in particular, Ba) from reacting with carbon dioxide or moisture in the air.

The furnace wall 3 comprises a port 7 for introducing oxygen gas from a mass flow controller 6 into the furnace; a port 9 connected to a pump 8 for evacuation; and a port 11 for introducing a gas from a mercury feeder 10 into the furnace. In the furnace, measuring units of a pressure gauge 12 and of a temperature instrument 14 are disposed. The temperature instrument 14 is connected to a temperature controller 13, which is connected with a heater wire 2 for controlling a temperature in the furnace.

A metal seal gate valve 16 is disposed between the port 11 and the mercury feeder 10. Around the metal seal gate valve 16 is wound a heater wire 15, which is connected to a temperature controller 17. The temperature controller 17 measures a temperature around the metal seal gate valve 16 using a temperature instrument 18 to adjust a temperature of the metal seal gate valve 16, taking the temperature measurement results into account. Thus, the configuration whereby a temperature of the metal seal gate valve 16 can be controlled can prevent mercury from being aggregated and adsorbed within the metal seal gate valve 16.

The mercury feeder 10 comprises a zirconia crucible (hereinafter, simply referred to as a “crucible”) 19, around which a heater wire 20 is wound. In the crucible 19 is disposed a measuring unit of a pressure gauge 24. On the periphery of the crucible 19 is disposed a measuring unit of a temperature instrument 22. The measuring unit of the temperature instrument 22 may be disposed within the crucible 19. The crucible 19 is filled with mercury oxide 23. A temperature controller 21 controls a temperature of the crucible 19 while monitoring the measurement results by the temperature instrument 22, to control a vapor pressure of mercury oxide 23 in the crucible 19. A pressure in the crucible 19 is also monitored by a pressure gauge 24. The mercury feeder 10 corresponds to a mercury gas generator.

The pressure vessel 1, the mercury feeder 10 and the metal seal gate valve 16 are contained in a housing 25. The housing 25 is connected with an exhaust duct 26 (exhauster) for forcibly exhausting the inside of the housing 25 and a pump 8 for forcibly exhausting the inside of the pressure vessel 1. Exhaust gases from the housing 25 and from the pump 8 are fed into an unshown scrubber to be harmless.

Temperature controllers 13, 17 and 21 and a mass flow controller 6 are placed outside of the housing 25. Thus, an operator can operate the apparatus from the outside of the housing 25. Even if a vapor of mercury oxide 23 leaks from the inside of the furnace, safety of the operator can be ensured.

The pressure vessel 1 is made of a metal such as stainless steel and treated with a chemical solution for form an oxide film on its surface so that the pressure vessel 1 may be resistant to oxygen gas or to mercury gas.

The surface of a seal in the manufacturing apparatus (e.g., a gasket, a metal O-ring and a metal seal in the metal seal gate valve 16) is coated with a metal such as Fe, Ni, Co and Mn, or an alloy mainly comprising a metal such as Fe, Ni, Co and Mn. It can prevent the seal from being amalgamated with mercury. Alternatively, the seal itself may be made of a metal such as Fe, Ni, Co and Mn or an alloy mainly comprising a metal such as Fe, Ni, Co and Mn.

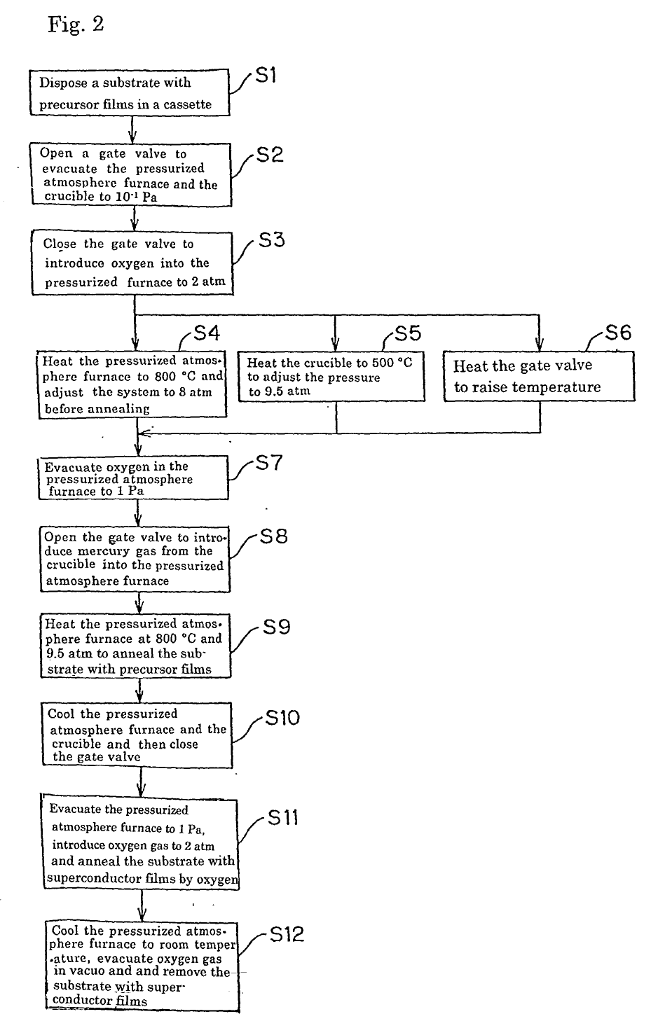

A process for forming a mercury-containing copper oxide superconductor film according to this invention will be described with reference to a process shown in FIG. 2.

At first, in a laser abrasion apparatus, using an Re_{0.18}Ba_{2.02}CaCu_{2.03}Oₓ target and an ReO target, on both sides of an MgO substrate 4 with a diameter of 3 inch at room temperature were deposited a precursor film to 50 nm and an ReO barrier film to 10 nm.

In the target composition for the precursor, a Cu ratio is slightly increased for improving superconductor properties, while a Ba ratio is also slightly increased for preparing for precipitation of BaCuO. For example, a Cu ratio is 7% or less and a cation ratio in the precursor film is determined such that a final cation ratio becomes higher than a stoichiometric ratio. In this process, several prototypes (e.g., three prototypes) may be made to determine a composition ratio by ICP analysis for feeding back the results, which may be utilized for determining a cation ratio in the precursor film. The cation ratio in the precursor film may be adjusted such that the final cation ratio becomes the stoichiometric ratio.

The Cu ratio may be adjusted to be 7% or less and higher than the stoichiometric ratio to produce a film exhibiting good superconductor properties such as a higher superconductive transition temperature in comparison with a film prepared with the stoichiometric ratio, although the amount of a Cu-containing precipitate is increased.

Then, six substrates 4 are inserted into a cassette 5 in place. The cassette 5 is placed in a pressurized atmosphere furnace at room temperature (step S1), and a metal seal gate valve 16 is opened to communicate the pressure vessel 1 and a crucible 19 at room temperature. Then, the insides of the furnace and the crucible are evacuated by a pump 8 to 10⁻¹ Pa (step S2).

Then, the metal seal gate valve 16 is closed to disconnect between the pressure vessel 1 and the crucible 19. Oxygen gas is introduced (fed) from a mass flow controller into the furnace and the inside of the furnace is pressurized to 2 atm (step S3).

A temperature controller 13 is operated to heat the inside of the furnace to 800° C. Since mercury gas is not fed during the process in the furnace, HgCaO₂ which is stable in a temperature range of around 500° C. and becomes a hetero phase is not formed. In other words, mercury gas is not introduced into the furnace in a temperature range where HgCaO₂ is stably formed. Then, after adjusting an oxygen pressure in the furnace to 8 atm, the film is annealed at 800° C. for 3 hours to remove carbon in the precursor film (step S4).

During the process, a temperature controller 21 is operated while shutting the metal seal gate valve 16, to heat the inside of the crucible 19 to about 500° C. Since mercury oxide 23 is decomposed into oxygen and mercury at about 500° C. so that a vapor pressure in the crucible 19 is rapidly increased. A temperature in the crucible 19 is, therefore, controlled to adjust a pressure in the crucible 19 to 9.5 atm while monitoring the pressure gauge 24 (step S5). At this point, about ⅔ of the total pressure of the gas atmosphere in the crucible 19 is a partial pressure of mercury and about ⅓ is a partial pressure of oxygen. A pressure of mercury oxide 23 is relatively smaller.

A temperature controller 17 is operated to heat the metal seal gate valve 16 (step S6). For example, the metal seal gate valve 16 is heated until it reaches a temperature higher by 30° C. or more than a preset temperature in the temperature controller 21.

Then, while maintaining the furnace at 800° C., oxygen gas in the furnace is evacuated to 1 Pa by a pump 8 (step S7). Then, while keeping a temperature in the crucible 19 constant by a temperature controller 21, the metal seal gate valve 16 is opened to introduce a mixture of mercury and oxygen gases from the crucible 19 to the furnace (step S8). In other words, mercury gas is not introduced until the internal temperature reaches a temperature at which a mercury-containing copper oxide superconductor film is thermodynamically stably and preferentially formed (800° C. or less). Once the furnace can be maintained at 800° C. and 9.6 atm, the precursor film is annealed for 5 hours to react the precursor film with mercury (step S9).

Then, while maintaining the temperature of the metal seal gate valve 16, the crucible 19 is rapidly cooled to room temperature and at the same time, the inside of the furnace is also rapidly cooled. When a temperature of the furnace becomes equal to a temperature of the metal seal gate valve 16, cooling of the metal seal gate valve 16 is initiated by operating the temperature controller 17. When a temperature of the metal seal gate valve 16 reaches 350° C., the metal seal gate valve 16 is shut (step S10). By the procedure described above, most of mercury oxide 23 is aggregated and adsorbed in the crucible 19 so that it can be readily recovered. Thus, such a procedure is effective in terms of environmental and safety practices.

Then, the furnace is evacuated by the pump 8 to 1 Pa and oxygen gas is introduced into the furnace to 2 atm. While maintaining the furnace at 300° C., the precursor film is annealed with oxygen for 3 hours (step S11). Then, the furnace is cooled to room temperature and after evacuating oxygen gas by the pump 8, the substrate 4 is removed from the furnace (step S12).

The process described above was conducted to form a (Hg_{0.8}Re_{0.2})Ba₂CaCu₂O_{6+δ} superconductor film (n=2) epitaxially grown along the c-axis on an MgO substrate. A temperature, a pressure and a precursor composition in this film formation may be changed to some extent to also form a mercury-containing copper oxide superconductor film with n=1 or 3.

A film formed as described above contains a reduced amount of impurities and exhibits no deteriorated superconductor properties due to carbon, in contrast to a film formed by a common conventional process using a quartz tube. When measuring a volume fraction from a peak intensity in X-ray spectrometry, a hetero-phase impurity HgCaO₂ is generally at a lower measurement limit or lower level and therefore not observed. Thus, a mercury-containing copper oxide superconductor film substantially composed of a single phase and substantially free of a hetero phase can be formed.

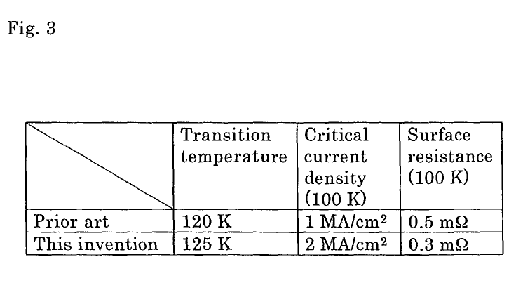

A film formed by the process described above exhibits improved superconductor properties in comparison with a film prepared by a common conventional manufacturing process. For example, the process of this invention provided a mercury-containing copper oxide superconductor film having a transition temperature higher by 5 K, a two-fold critical current density and a reduced surface resistance by 40% in comparison with a common conventional manufacturing process, as seen in FIG. 3.

In this embodiment, a film is formed in a pressure vessel 1 which is a large volume sealed vessel rather than a small volume sealed vessel such as a quartz tube so that a large area film can be formed. A large area film applicable to an electronic device such as a filter for a mobile telecommunication system can be produced in a large scale. The reaction becomes insusceptible to variation in, e.g., the amount of mercury or an area of the precursor film. Since vapor pressure equilibrium is used in the crucible 19, a partial pressure of mercury is independent of the amount of mercury charged in the crucible and dependent on a temperature of the crucible 19 alone. It can, therefore, eliminate the necessity of precise calculation of the amount of mercury.

This embodiment of this invention, therefore, provides a mercury-containing copper oxide superconductor film exhibiting good superconductor properties with a large area and a reduced amount of precipitated impurities as a hetero phase. This embodiment also provides an apparatus and a process for safely and with a large scale forming a mercury-containing copper oxide superconductor film.

The above embodiment has been described with reference to an example in which mercury oxide 23 is used as a material for generating mercury gas, but mercury or another mercury compound such as mercury chloride may be used instead of mercury oxide 23. For example, if mercury chloride is used, a reaction for forming a sintered mercury-containing copper oxide superconductor is accelerated.

As described above, a large area mercury-containing copper oxide superconductor film substantially free of a hetero phase can be provided using an apparatus for forming a mercury-containing copper oxide film comprising a pressurized atmosphere furnace equipped with a port for introducing an external gas atmosphere to the furnace wall and a mercury gas generator for controlling a pressure of the gas atmosphere independently of the pressurized atmosphere furnace by generating a mercury-containing gas, wherein the mercury gas generator introduces a mercury-containing gas into the pressurized atmosphere furnace via the port.

What is claimed is:

1. A mercury-containing copper oxide superconductor film which is substantially made of a single phase and is free of a hetero phase.

2. The mercury-containing copper oxide superconductor film as claimed in claim 1 containing HgCaO₂ as a hetero phase at a volume fraction of 5% or less.

3. An apparatus for producing a mercury-containing copper oxide superconductor film comprising:
a system for controlling a temperature of a mercury-containing gas atmosphere; and
a system for controlling a pressure of a gas atmosphere independently of the temperature of the mercury-containing gas atmosphere.

4. The apparatus for producing a mercury-containing copper oxide superconductor film as claimed in claim 3 comprising:
a pressurized atmosphere furnace equipped with a port for introducing an external gas atmosphere to the furnace wall as the system for controlling a temperature of a mercury-containing gas atmosphere; and
a mercury gas generator for controlling a pressure of the gas atmosphere independently of the pressurized atmosphere furnace by generating a mercury-containing gas as the system for controlling a pressure of a gas atmosphere independently of the temperature of the mercury-containing gas atmosphere;
wherein the mercury gas generator introduces a mercury-containing gas into the pressurized atmosphere furnace via the port.

5. The apparatus for producing a mercury-containing copper oxide superconductor film as claimed in claim 4 comprising a gate valve between the pressurized atmosphere furnace and the mercury gas generator.

6. The apparatus for producing a mercury-containing copper oxide superconductor film as claimed in claim 5 wherein the gate valve is a metal seal type gate valve and a structure which can heat the metal seal gate valve is provided.

7. The apparatus for producing a mercury-containing copper oxide superconductor film as claimed in claim 4 wherein the mercury gas generator comprises a crucible for generating a mercury-containing gas atmosphere by heating a mercury-containing composition to control a pressure of the gas atmosphere utilizing vapor pressure equilibrium.

8. The apparatus for producing a mercury-containing copper oxide superconductor film as claimed in claim 5 wherein the mercury gas generator comprises a crucible for generating a mercury-containing gas atmosphere by heating a mercury-containing composition to control a pressure of the gas atmosphere utilizing vapor pressure equilibrium.

9. The apparatus for producing a mercury-containing copper oxide superconductor film as claimed in claim 6 wherein the mercury gas generator comprises a crucible for generating a mercury-containing gas atmosphere by heating a mercury-containing composition to control a pressure of the gas atmosphere utilizing vapor pressure equilibrium.

10. The apparatus for producing a mercury-containing copper oxide superconductor film as claimed in claim 4 wherein a component used in a seal in the apparatus is made of Fe, Ni, Co, Mn or an alloy mainly comprising Fe, Ni, Co or Mn, or is coated with Fe, Ni, Co, Mn or an alloy mainly comprising Fe, Ni, Co or Mn.

11. The apparatus for producing a mercury-containing copper oxide superconductor film as claimed in claim 5 wherein a component used in a seal in the apparatus is made of Fe, Ni, Co, Mn or an alloy mainly comprising Fe, Ni, Co or Mn, or is coated with Fe, Ni, Co, Mn or an alloy mainly comprising Fe, Ni, Co or Mn.

12. The apparatus for producing a mercury-containing copper oxide superconductor film as claimed in claim 6 wherein a component used in a seal in the apparatus is made of Fe, Ni, Co, Mn or an alloy mainly comprising Fe, Ni, Co or Mn, or is coated with Fe, Ni, Co, Mn or an alloy mainly comprising Fe, Ni, Co or Mn.

13. The apparatus for producing a mercury-containing copper oxide superconductor film as claimed in claim 7 wherein a component used in a seal in the apparatus is made of Fe, Ni, Co, Mn or an alloy mainly comprising Fe, Ni, Co or Mn, or is coated with Fe, Ni, Co, Mn or an alloy mainly comprising Fe, Ni, Co or Mn.

14. The apparatus for producing a mercury-containing copper oxide superconductor film as claimed in claim 8 wherein a component used in a seal in the apparatus is made of Fe, Ni, Co, Mn or an alloy mainly comprising Fe, Ni, Co or Mn, or is coated with Fe, Ni, Co, Mn or an alloy mainly comprising Fe, Ni, Co or Mn.

15. The apparatus for producing a mercury-containing copper oxide superconductor film as claimed in claim 9 wherein a component used in a seal in the apparatus is made of Fe, Ni, Co, Mn or an alloy mainly comprising Fe, Ni, Co or Mn, or is coated with Fe, Ni, Co, Mn or an alloy mainly comprising Fe, Ni, Co or Mn.

16. The apparatus for producing a mercury-containing copper oxide superconductor film as claimed in any one of claims 4 to 15 further comprising a housing enclosing an apparatus unit inside of which is filled with a mercury-containing gas atmosphere and an exhauster for forcibly exhausting the inside of the housing.

17. A process for producing a mercury-containing copper oxide superconductor film comprising the steps of:
forming a precursor film comprising a mercury-containing copper oxide superconductor composite on a substrate and placing the product in a furnace;
controlling a furnace temperature while controlling a pressure of the mercury-containing gas atmosphere independently of temperature control; and
introducing gaseous mercury to the precursor film disposed within the furnace and diffusing mercury in the precursor film or reacting mercury with the film.

18. The process for producing a mercury-containing copper oxide superconductor film as claimed in claim 17 wherein mercury is fed into the furnace under the conditions such that mercury can be diffused in or reacted with the precursor film to form a sintered mercury-containing copper oxide superconductor.

19. The process for producing a mercury-containing copper oxide superconductor film as claimed in claim 18 wherein using MgO as a material for a substrate, mercury is introduced into the furnace while maintaining the furnace at an internal temperature of 800° C. or less.

20. The process for producing a mercury-containing copper oxide superconductor film as claimed in claim 17 wherein a plurality of prototypes of a mercury-containing copper oxide superconductor are made for adjusting a final cation ratio to a stoichiometric ratio or for determining a cation ratio in the precursor film such that the ratio is higher than the stoichiometric ratio and a Cu composition ratio is 7% or less.

21. The process for producing a mercury-containing copper oxide superconductor film as claimed in claim 18 wherein a plurality of prototypes of a mercury-containing copper oxide superconductor are made for adjusting a final cation ratio to a stoichiometric ratio or for determining a cation ratio in the precursor film such that the ratio is higher than the stoichiometric ratio and a Cu composition ratio is 7% or less.

22. The process for producing a mercury-containing copper oxide superconductor film as claimed in claim 19 wherein a plurality of prototypes of a mercury-containing copper oxide superconductor are made for adjusting a final cation ratio to a stoichiometric ratio or for determining a cation ratio in the precursor film such that the ratio is higher than the stoichiometric ratio and a Cu composition ratio is 7% or less.

23. The process for producing a mercury-containing copper oxide superconductor film as claimed in any one of claims 17 to 22 wherein the internal temperature of the furnace reaches a temperature at which the mercury-containing copper oxide superconductor is thermodynamically stably formed, before introducing mercury.
